(19) United States
(12) Patent Application Publication
(10) Pub. No.: US 2010/0030500 A1
(43) Pub. Date: Feb. 4, 2010

(54) Regulation of Power Consumption for Application-Specific Integrated Circuits

(76) Inventors: Gamal REFAI-AHMED, Markham (CA); Sagheer AHMAD, Cupertino, CA (US)

Correspondence Address: STERNE, KESSLER, GOLDSTEIN & FOX P.L.L.C., 1100 NEW YORK AVENUE, N.W., WASHINGTON, DC, 20005, US

(21) Appl. No.: 12/268,924

(22) Filed: Nov. 11, 2008

Related U.S. Application Data
(60) Provisional application No. 61/084,503, filed on Jul. 29, 2008.

(51) Int. Cl. G01R 19/00

(52) U.S. Cl. 702/64

(57) ABSTRACT

Provided are systems, methods, and computer program products for regulating power consumption in application-specific integrated circuits (ASICs)—such as, for example, a graphics processing unit. In such a method, a value of a leakage current of an ASIC is received from computer-readable information contained in the ASIC. One or more operational parameters of the ASIC—such as, for example, a supply voltage to the ASIC, a engine speed of the ASIC, and/or a fan speed of a fan used to cool the ASIC—are adjusted based on the value of the leakage current of the ASIC. Optionally, the one or more operational parameters may also be adjusted based on a type of application running on the ASIC. In addition, a supply voltage to the ASIC may (optionally) be shut off if the temperature of the ASIC exceeds a threshold.

### CROSS REFERENCE TO RELATED APPLICATIONS

This application claims benefit under 35 U.S.C. §119(e) to U.S. Provisional Patent Application 61/084,503, entitled “Regulation of Power Consumption for Application-Specific Integrated Circuits,” to Refai-Ahmed et al., filed on Jul. 29, 2008, the entirety of which is hereby incorporated by reference as if fully set forth herein.

### BACKGROUND OF THE INVENTION

1. Field of the Invention

The present invention is generally directed to computing devices, and more particularly directed to application-specific integrated circuits included in computing devices.

2. Background Art

An application-specific integrated circuit (ASIC) is an integrated circuit that is designed to perform a specific application. For example, a graphics-processing unit (GPU) is a type of ASIC that is designed to perform graphics-processing tasks. To build an ASIC, a collection of transistors and other circuit elements are fabricated on a single crystalline substrate (such as a silicon substrate).

Unfortunately, even if a single type of crystalline substrate is used to fabricate ASICs, the ASICs across a product line typically may have a wide range of leakage currents—i.e., current flows along undesired paths. The wide range of leakage currents of ASIC-based products can lead to a wide range of power consumption within the ASIC-based products because an ASIC with a high leakage current will consume more power than an ASIC with a low leakage current. The wide range of power consumption across a line of ASIC-based products is problematic for several reasons.

First, the wide range of power consumption across a line of ASIC-based products (such as, for example, a line of graphics cards) may lead to a higher power budget of a system platform (such as, for example, a computer platform) that includes the line of ASIC-based products. The products in the line may be configured to operate at a target power (such as, for example, 70 watts) during normal operating conditions. In extreme operating conditions, however, a small minority of the products in the line may operate at a higher power (such as, for example, 200 watts). The system-platform developer must plan for the worst power consumption of the products in the product line (e.g., 200 watts)—even if the worst power consumption only has a probability of occurring less than 1% of the time.

Moreover, the wide range of power consumption across a line of ASIC-based products may lead to a more expensive product line. A vendor typically manufactures ASIC-based products to operate at an advertised engine speed (such as, for example, 4 gigahertz). In order to perform at the same engine speed, an ASIC with a low leakage current requires a high supply voltage and an ASIC with a high leakage current requires a low supply voltage. Because the ASICs in a single manufacturing yield typically have a wide range of leakage currents, the ASICs from the single manufacturing yield would require a wide range of supply voltages to perform at the advertised engine speed. The wide range of supply voltages would, in turn, lead to a wide range of power consumption across the ASICs in the single manufacturing yield. If the power consumption across the ASICs does not fall within a desired range, the vendor could select only the percentage of the ASICs in the manufacturing yield that consume power within the desired range—which effectively reduces the efficiency of the manufacturing yield. To recoup the cost of the reduced efficiency in the manufacturing yield, the vendor typically increases the price of each ASIC-based product in the product line.

A potential solution for dealing with the wide range of power consumption across a line of ASIC-based products is to earmark ASICs for certain applications based on the leakage current of the ASICs. For example, an ASIC with a low leakage current may be earmarked for use in a mobile computing device (in which efficient power consumption is an important factor), whereas an ASIC with a high leakage current may be earmarked for use in a desktop computer (in which efficient power consumption is not a very important factor). But this type of earmarking solution is still problematic.

As an initial matter, some ASICs may be used only in environments in which efficient power consumption is paramount. For example, some ASICs may be designed to work in only mobile computing devices. An earmarking solution would not be effective for such ASICs.

In addition, an earmarking solution does not address the inefficiencies associated with an ASIC having a high leakage current. With the increased awareness of global climate change, consumers are placing more and more emphasis on efficient power consumption. This emphasis will likely only increase in the years to come. In addition to consumers' desire for efficient power consumption, new energy standards may soon require efficient power consumption in ASIC-based products.

Furthermore, while an earmarking solution may be effective across a line of ASIC-based products, an earmarking solution does not address issues associated with a single ASIC-based product. For example, an earmarking solution does not help reduce undesirable acoustic noise from a fan used to cool an ASIC-based product. Nor does an earmarking solution address, for example, performance variations of an ASIC-based product that may occur due to the wide range of operating conditions to which the ASIC-based product may be subjected.

Given the foregoing, what is needed are methods, systems, and computer program products for regulating power consumption in ASICs.

### BRIEF SUMMARY OF THE INVENTION

The present invention is directed to regulating power consumption in ASICs, such as GPUs. Importantly, aspects of the present invention reduce the cost of a power budget and improve a manufacturing yield. In addition, aspects of the present invention are configured to provide improved acoustic noise performance and comply with new energy standards (such as, for example, Energy Star).

An embodiment of the present invention provides a computer-based method for regulating power consumption in an ASIC. In this computer-based method, a value of a leakage current of the ASIC is received from computer-readable information contained in the ASIC. Then, one or more operational parameters of the ASIC—such as, for example, a supply voltage to the ASIC, a engine speed of the ASIC, and/or a fan speed of a fan used to cool the ASIC—are adjusted based on the value of the leakage current of the ASIC. Optionally, the one or more operational parameters may be further adjusted based on a type of application running on the ASIC. In addition, power to the ASIC may (optionally) be shut off if the temperature of the ASIC exceeds a threshold.

Another embodiment of the present invention provides a computer-program product including a computer-readable storage medium having control logic stored therein for causing a computer to regulate power consumption in an ASIC. The control logic includes first and second computer-readable program code. The first computer-readable program code is configured to cause the computer to receive a value of a leakage current of the ASIC. The second computer-readable program code is configured to cause the computer to adjust one or more operational parameters of the ASIC based on the value of the leakage current of the ASIC.

A further embodiment of the present invention provides a computing device. The computing device includes an ASIC and a machine-readable storage medium. The machine-readable storage medium has control logic stored therein for causing the computing device to regulate power consumption in the ASIC. The control logic includes first and second machine-readable program code. The first machine-readable program code is configured to cause the computing device to receive a value of a leakage current from an ASIC. The second machine-readable program code is configured to cause the computing device to adjust one or more operational parameters of the ASIC based on the value of the leakage current of the ASIC. The computing device may comprise, for example, a computer, a video-game device, a mobile telephone, a personal digital assistant (PDA), a hand-held device, or some other type of device having an ASIC and configured to execute machine-readable program code.

Further features and advantages of the invention, as well as the structure and operation of various embodiments of the invention, are described in detail below with reference to the accompanying drawings.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1 depicts a block diagram illustrating an example computing device.

FIG. 2 depicts a block diagram illustrating an example graphics card.

FIG. 3 depicts a block diagram illustrating an example work flow for processing graphics.

FIG. 4 depicts a graph illustrating a substantially constant power consumption of a GPU across different leakage currents by varying a temperature of and supply voltage to the GPU.

FIG. 5 depicts a block diagram illustrating an example method for adjusting one or more operational parameters of a GPU based on a leakage current and temperature of the GPU.

FIG. 6 depicts a block diagram illustrating an example method for adjusting one or more operational parameters of a GPU based on a leakage current of and type of application running on the GPU.

FIG. 7 depicts a graph illustrating the relationship of power consumption and supply voltage for low and high leakage current as the power consumption and supply voltage vary with temperature.

FIG. 8 depicts a graph illustrating the relationship of fan capacity and engine speed as the fan capacity and engine speed vary with temperature.

FIG. 9 depicts a graph illustrating a power consumption, fan capacity, and engine speed as the power consumption, fan capacity, and engine speed vary with temperature.

The features and advantages of the present invention will become more apparent from the detailed description set forth below when taken in conjunction with the drawings, in which like reference characters identify corresponding elements throughout.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION OF THE INVENTION

### I. INTRODUCTION

The present invention is directed to regulating power consumption in ASICs. In the detailed description that follows, references to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For illustrative purposes, and not limitation, power regulation in accordance with an embodiment of the present invention is described herein in terms of a power-regulated GPU. It is to be appreciated, however, that such power regulation is applicable to other types of ASICs. Based on the description contained herein, a person skilled in the relevant art(s) will understand how to implement power regulation in other types of ASICs.

In an embodiment, power consumption in a GPU is regulated based on the leakage current of the GPU. The leakage current of the GPU may be obtained, for example, by using conventional automatic test equipment (ATE) after the GPU is fabricated. The value of the leakage current may then be included within computer-readable information contained in the GPU. For example, the value of the leakage current may be registered in the computer-readable information by using eFUSE technology developed by IBM Corp. of Armonk, N.Y.

During operation, one or more operational parameters of the GPU are adjusted based on the value of the leakage current of the GPU. The one or more operational parameters may include but are not limited to a supply voltage to the GPU, an engine speed of the GPU, a fan speed of a fan used to cool the GPU, or some other operational parameter of a GPU as would be apparent to a person skilled in the relevant art(s). Optionally, the one or more operational parameters may be further adjusted based on a type of application running on the GPU and/or based on the ambient conditions to which the GPU is subjected. In addition, power to the GPU may (optionally) be shut off if the temperature of the GPU exceeds a threshold.

By regulating power consumption of a GPU in accordance with an embodiment of the present invention, the GPU can consume substantially less power than that same GPU would consume if it operated in a conventional manner. For example, whereas a GPU may conventionally consume approximately X watts of power, that same GPU would consume approximately 0.67× watts to approximately 0.77× watts by regulating power consumption in accordance with an embodiment of the present invention.

And a graphics card of the GPU would also consume less power than a conventional graphics card if the power consumption of the GPU is regulated in accordance with an embodiment of the present invention. From the example above, whereas a graphics card may conventionally consume approximately 1.4× watts of power, that same graphics card would consume approximately 1.2× watts by regulating power consumption in accordance with an embodiment of the present invention. As a result, an original equipment manufacturer (OEM) that uses a power-regulated graphics card in accordance with an embodiment of the present invention would budget only 1.2× watts of power per card, whereas that OEM would have to budget 1.4× watts of power per card for a conventional graphics card.

A power-regulated GPU in accordance with an embodiment of the present invention may be couched in a computing device that includes a GPU. An example hardware implementation of such a computing device and the operation thereof are described in more detail below.

### II. AN EXAMPLE SYSTEM

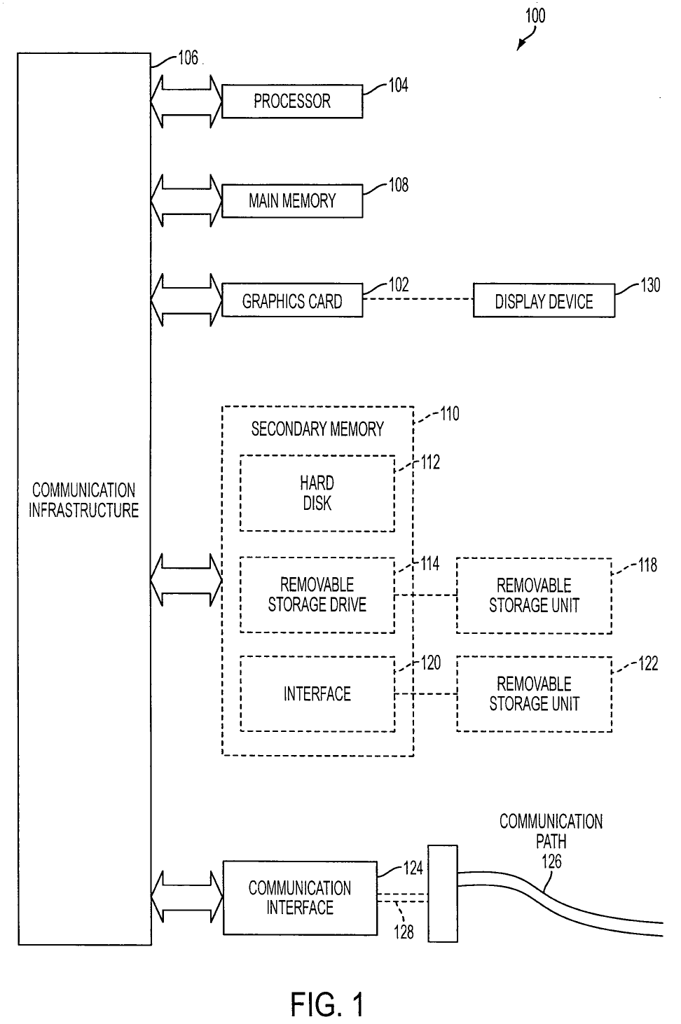

FIG. 1 depicts a block diagram illustrating an example computing device 100 that regulates power in a GPU in accordance with an embodiment. Computing device 100 may comprise a desktop computer, a laptop computer, a video-game device, a hand-held device (such as, for example, a mobile telephone or a personal digital assistant (PDA)), or some other type of computing device that includes a GPU. Referring to FIG. 1, computing device 100 includes a processor 104, a graphics card 102, and main memory 108, and optionally includes secondary memory 110 and communications interface 124. Processor 104 and graphics card 102 communicate with each other and main memory 108, secondary memory 110, and communications interface 124 over communication infrastructure 106. Communication infrastructure 106 may include for example, a peripheral component interface (PCI) bus, an accelerated graphics port (AGP) bus, a PCI Express (PCIE) bus, or some other type of communications bus.

Processor 104 comprises a general-purpose processor, such as a central processor unit (CPU). Processor 104 performs general-purpose processing tasks.

Graphics card 102 includes a GPU and other components to assist processor 104 by performing certain special functions, usually faster than processor 104 could perform them in software. Graphics card 102 is coupled to a display device 130. Graphics card 102 forwards graphics, text, and other data for display to display unit 130.

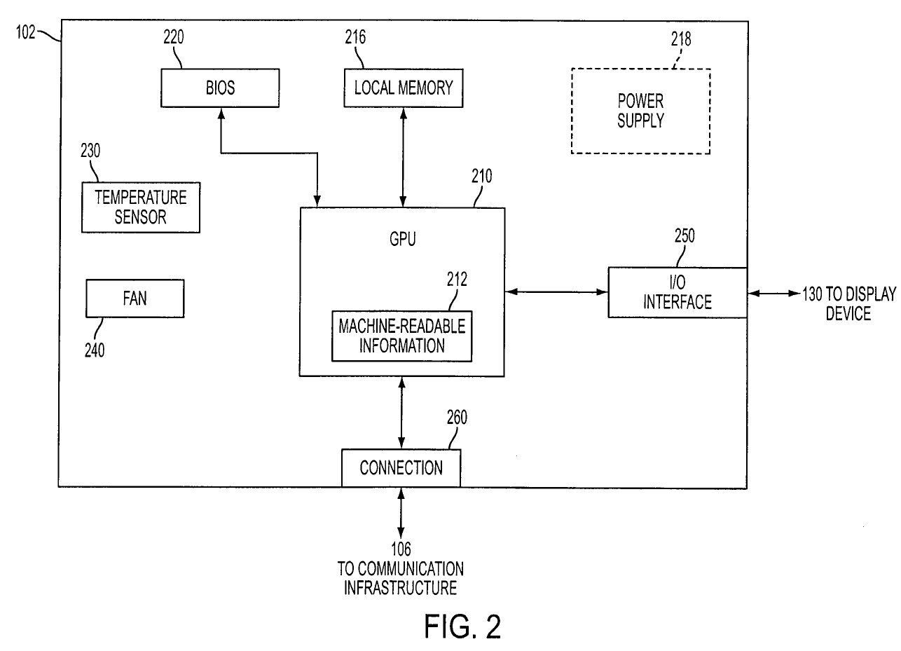

For example, FIG. 2 depicts a block diagram of an example implementation of graphics card 102. Power to graphics card 102 may be supplied by power supply 218 included on graphics card 102 or by computing device 100. As illustrated in FIG. 2, graphics card 102 includes a GPU 210 and a basic input/output system (BIOS) 220.

GPU 210 performs graphics processing tasks for computing device 100, and may temporarily store data in local memory 216. GPU 210 is coupled to display device 130 via input/output (I/O) interface 250 and communication infrastructure 106 via connection 260. GPU 210 includes machine-readable information 212 that identifies the value of the leakage current of GPU 210. The value of the leakage current of GPU 210 may be determined using automatic test equipment after GPU 210 is fabricated. This value may then be included in machine-readable information 212 using, for example, eFUSE technology developed by IBM Corp. of Armonk, N.Y. In an embodiment, software running on computing device 100 adjusts one or more operational parameters of GPU 210 based on the value of the leakage current contained in machine-readable information 212, as described in more detail herein.

BIOS 220 includes a set of video-related functions that are used by programs to access the video hardware chipset (including, for example, GPU 210). BIOS 220 interfaces software to the video chipset in much the same way that the system BIOS does for the chipset of computing device 100. When computing device 100 is started, it may display, for example, the graphics card vendor, model, BIOS version and amount of graphics memory. In an embodiment, BIOS 220 also includes a function for regulating power consumption in GPU 210 based on (i) the value of the leakage current of GPU 210 included in machine-readable information 212 and/or (ii) the operating conditions of GPU 210. For example, the function for regulating power consumption in GPU 210 may adjust
the speed of fan 240 (based on, for example, the temperature sensed by temperature sensor 230),
the engine speed of GPU 210, and/or
the power supplied to GPU 210.
   Example functions for regulating power consumption in GPU 210 are described in more detail below.

Referring again to FIG. 1, computing device 100 also includes main memory 108 and secondary memory 110. Main memory 108 may preferably be random access memory (RAM). Secondary memory 110 may include, for example, a hard disk drive 112 and/or a removable storage drive 114. Removable storage drive 114 reads from and/or writes to a removable storage unit 118 in a well known manner. Removable storage unit 118 may comprise a floppy disk, magnetic tape, optical disk, or some other type of computer-readable storage medium which is read by and written to by removable storage drive 114. In other words, removable storage unit 118 includes a computer usable storage medium having stored therein computer software and/or data.

Secondary memory 110 may include other similar devices for allowing computer programs or other instructions to be loaded into computing device 100. Such devices may include, for example, a removable storage unit 122 and an interface 120. Examples of such may include a program cartridge and cartridge interface (such as that found in video game devices), a removable memory chip (such as an erasable programmable read only memory (EPROM), or programmable read only memory (PROM)) and associated socket, and other removable storage units 122 and interfaces 120, which allow software and/or data to be transferred from removable storage unit 122 to computing device 100.

Communications interface 124 allows software and/or data to be transferred between computing device 100 and external devices. Examples of communications interface 124 may include a modem, a network interface (such as an Ethernet card), a communications port, a Personal Computer Memory Card International Association (PCMCIA) slot and card, etc. Software and/or data transferred via communications interface 124 are in the form of signals 128 which may be electronic, electromagnetic, optical or other signals capable of being received by communications interface 124. Signals 128 are provided to communications interface 124 via a communications path (e.g., channel) 126. Communications path 126 carries signals 128 and may be implemented using wire or cable, fiber optics, a telephone line, a cellular link, an radio frequency (RF) link and other communications channels.

Computer programs (also referred to as computer control logic) are stored in a computer-readable storage medium—such as, for example, main memory 108, secondary memory 110, and/or BIOS 220. Computer programs may also be received via communications interface 124. Such computer programs, when executed, enable the computing device 100 to regulate power consumption by GPU 210. Example operation of such computer programs are described in more detail below.

### III. EXAMPLE OPERATION

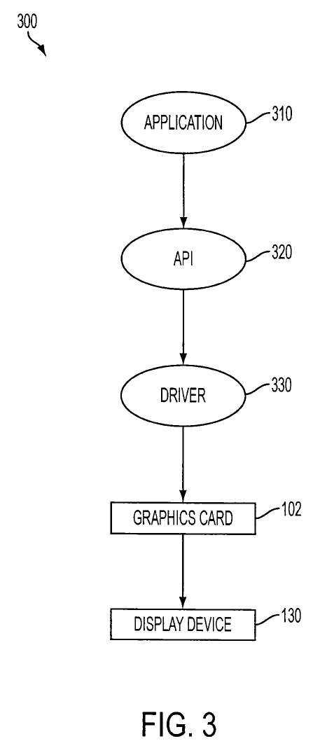

FIG. 3 depicts a block diagram 300 illustrating an example process flow in accordance with an embodiment of the present invention. Block diagram 300 includes various software elements—such as an application 310, an application programming interface (API) 320, and a driver 330—that are executed on a host computing system (such as computing device 100) and interact with graphics hardware elements (such as graphics card 102 and GPU 210) to perform graphics processing tasks for output to display device 130.

Application 310 is an end-user application that requires graphics processing capability (such as, for example, a video-game application, a CAD application, a CAM application, or the like). Application 310 communicates with API 320.

API 320 is an intermediary between application software, such as application 310, and graphics hardware on which the application software runs. With new chipsets and entirely new hardware technologies appearing at an increasing rate, it is difficult for application developers to take into account, and take advantage of, the latest hardware features. It is also increasingly difficult for application developers to write applications specifically for each foreseeable set of hardware. API 320 prevents application 310 from having to be too hardware specific. Application 310 can output graphics data and commands to API 320 in a standardized format, rather than directly to the hardware (e.g., graphics card 102 and GPU 210). API 320 may comprise a commercially available API (such as, for example, Direct® or OpenGL®), a custom API, or the like. API 320 communicates with driver 330.

Driver 330 is typically written by the manufacturer of the graphics hardware, and translates standard code received from API 320 into native format understood by graphics card 102 and GPU 210. Driver 330 also accepts input to direct performance settings for graphics card 102 and GPU 210. Such input may be provided by a user, an application or a process. For example, a user may provide input by way of a user interface (UI), such as a graphical user interface (GUI), that is supplied to the user along with driver 330. In an embodiment, driver 320 includes functions for regulating power consumption of GPU 210 in accordance with an embodiment of the present invention.

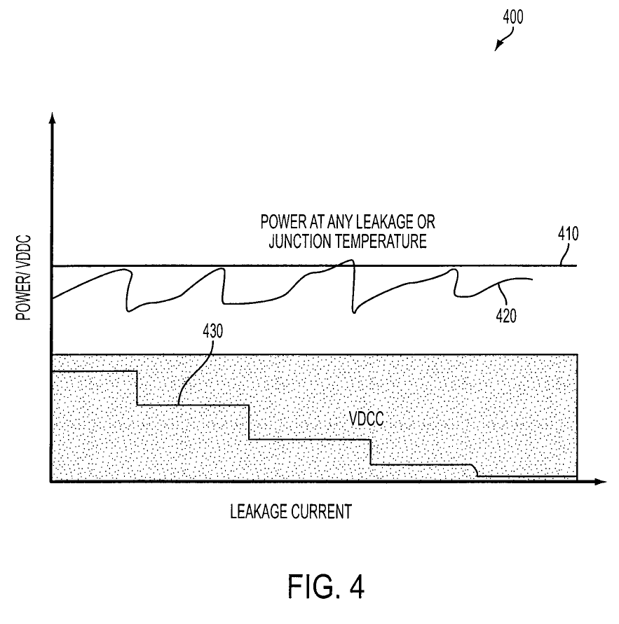

For example, FIG. 4 depicts a graph 400 illustrating how power consumption of a GPU may be kept substantially constant over different leakage currents. Referring to FIG. 4, curve 410 represents the power consumption of the GPU as a function of leakage current; curve 420 represents the junction temperature of the GPU as a function of leakage current; and curve 430 represents the supply voltage to the GPU as a function of leakage current. As explained in more detail below, the power consumption of a GPU may be kept substantially constant by varying the junction temperature of the GPU and/or the supply voltage to the GPU.

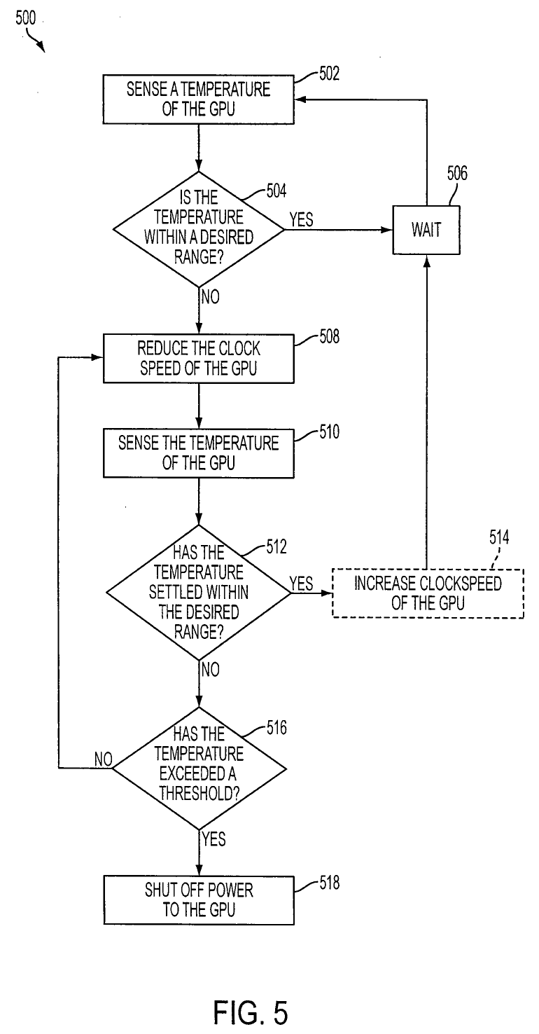

FIG. 5 depicts a flow diagram 500 illustrating an example method for regulating power consumption of a GPU by controlling the temperature of the GPU. Flow diagram 500 begins at a step 502 in which a temperature of the GPU is sensed. The temperature of the GPU may be sensed by using a temperature sensor (such as temperature sensor 230 of FIG. 1).

In step 504, it is determined whether the temperature of the GPU is within a desired range. If, on the one hand, the temperature is within the desired range, then the temperature is sensed again after (optionally) waiting for a delay period (as indicated in step 506). If, on the other hand, the temperature is not within the desired range, then the engine speed of the GPU is reduced as indicated in step 508.

After reducing the engine speed, the temperature of the GPU is sensed again as indicated in step 510. In a decision step 512, it is determined whether the temperature of the GPU has settled within the desired range. If, on the one hand, the temperature has settled within the desired range, then the engine speed of the GPU may (optionally) be increased as indicated in a step 514 and the method returns to step 502. If, on the other hand, the temperature has not settled within the desired range, then in a step 516 it is determined whether the temperature has exceeded a threshold (such as, for example, 120° C.).

If, in step 516, the temperature of the GPU has exceeded the threshold, then power to the GPU is shut off as indicated in a step 518. On the other hand, if the temperature of the GPU has not exceeded the threshold, then the method returns to step 508 and the engine speed of the GPU is reduced.

By implementing the example method illustrated in FIG. 5, the performance of the GPU (i.e., the engine speed) may be gradually reduced as the temperature of the GPU increases. In this way, power to the GPU is shut off only if the gradual reduction in performance does not curb the increasing temperature of the GPU.

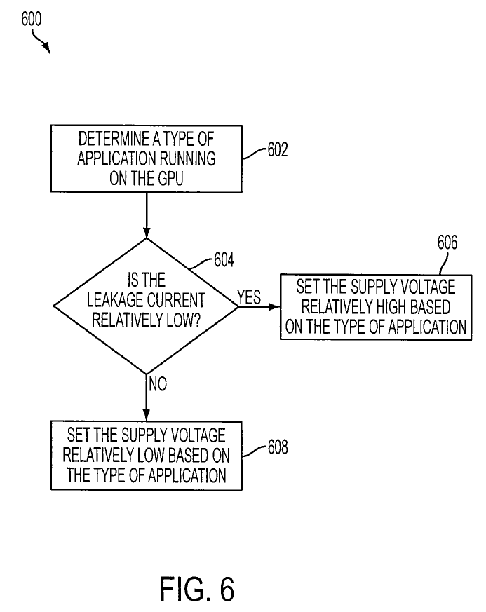

FIG. 6 depicts a flow diagram 600 illustrating an example method for regulating power consumption of a GPU based on an application running on the GPU. Flow diagram 600 begins at a step 602 in which a type of application running on the GPU is determined. For example, it may be determined that the GPU is running a 3D application or a 2D application or that the GPU is idle.

In a step 604, it is determined whether the leakage current of the GPU is relatively low. Referring to the example system of FIGS. 1 and 2, computing device 100 determines whether the leakage current of GPU 210 is relatively low by reading machine-readable information 212 contained in GPU 210.

If, one the one hand, the leakage current of the GPU is relatively low, then in step 606 the supply voltage to the GPU is set relatively high based on the type of application running on the GPU. If, on the other hand, the leakage current of the GPU is not relatively low, then in step 608 the supply voltage to the GPU is set relatively high based on the type of application running on the GPU in order to maintain the same engine speed of the GPU for each type of application. Example supply voltages for GPUs having relatively low and relatively high leakage currents are respectively illustrated in the left- and right-hand columns of Table 1. By adjusting the supply voltage to the GPU based on the type of application running on the GPU, the engine speed of the GPU can be maintained at a substantially desired level.

TABLE 1

| | Relatively Low | | Relatively High | |
|---|---|---|---|---|
| | Leakage Current | | Leakage Current | |
| Idle | 0.5 | volts | 0.4 | volts |
| 2D app. | 0.75 | volts | 0.65 | volts |
| 3D app. | 1 | volt | 0.9 | volts |

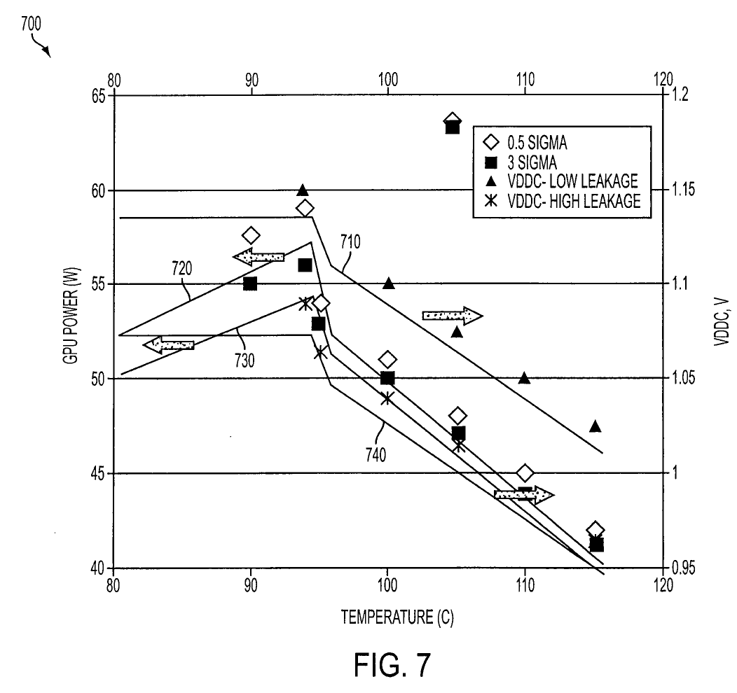

FIGS. 7-9 depict graphs illustrating how temperature, supply voltage, and fan speed can be controlled to regulate power consumption of an example GPU—namely, the RV670 graphics chip offered by AMD of Sunnyvale, Calif. It is to be appreciated, however, that FIGS. 7-9 are presented for illustrative purposes only, and not limitation. The curves depicted in FIGS. 7-9 would likely change for a different type of graphics chip and/or a different type of ASIC.

FIG. 7 depicts a graph 700 illustrating the relationship of power consumption and supply voltage for low and high leakage current as the power consumption and supply voltage vary with temperature. Graph 700 includes four curves—a first curve 710, a second curve 720, a third curve 730, and a fourth curve 740. First curve 710 represents the supply voltage (VDDC) to the GPU at different temperatures when the leakage current is low, and fourth curve 740 represents the supply voltage to the GPU at different temperatures when the leakage current is high. The vertical axis scale for first curve 710 and fourth curve 740 is shown on the right side of graph 700, and ranges from approximately 0.95 volts to approximately 1.2 volts. In a similar manner, second curve 720 represents the power consumption of the GPU at different temperatures when the leakage current is low, and third curve 730 represents the power consumption of the GPU at different temperatures when the leakage current is high. The vertical axis scale for second curve 720 and third curve 730 is shown on the left side of graph 700, and ranges from approximately 40 watts to approximately 65 watts. Because second curve 720 and third curve 730 are relatively close for temperatures exceeding 95° C., graph 700 illustrates that the power consumption of the example GPU may be regulated within a relativey tight range when the example GPU has either high or low leakage current.

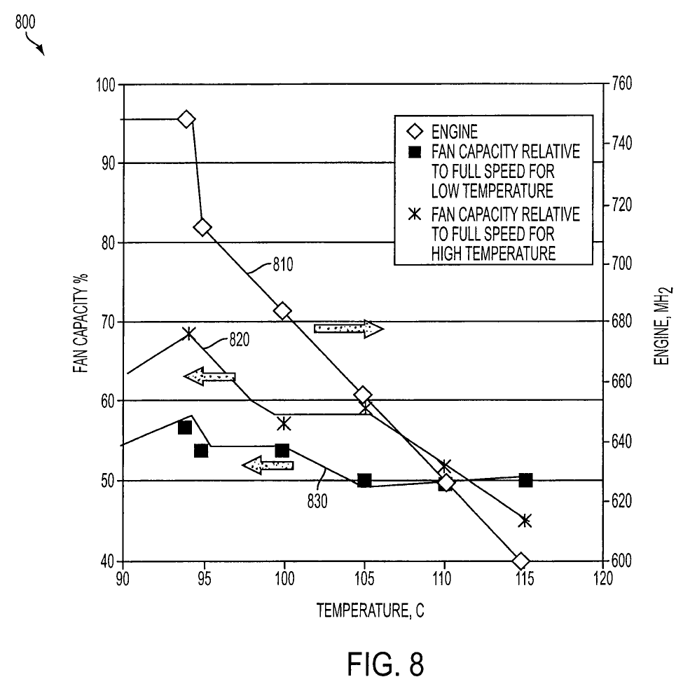

FIG. 8 depicts a graph 800 illustrating the relationship of fan capacity and engine speed as the fan capacity and engine speed vary with temperature. Graph 800 includes three curves—a first curve 810, a second curve 820, and a third curve 830. First curve 810 represents the engine speed of the GPU at different temperatures. The vertical axis scale for first curve 810 is shown on the right side of graph 800, and ranges from approximately 600 MHz to approximately 760 MHz. In a similar manner, second curve 820 represents the percentage of fan capacity for high temperature, and third curve 830 represents the percentage of fan capacity for low temperature. The vertical axis scale for second curve 820 and third curve 830 is shown on the left side of graph 800, and ranges from approximately 40% of fan capacity to approximately 100% of fan capacity.

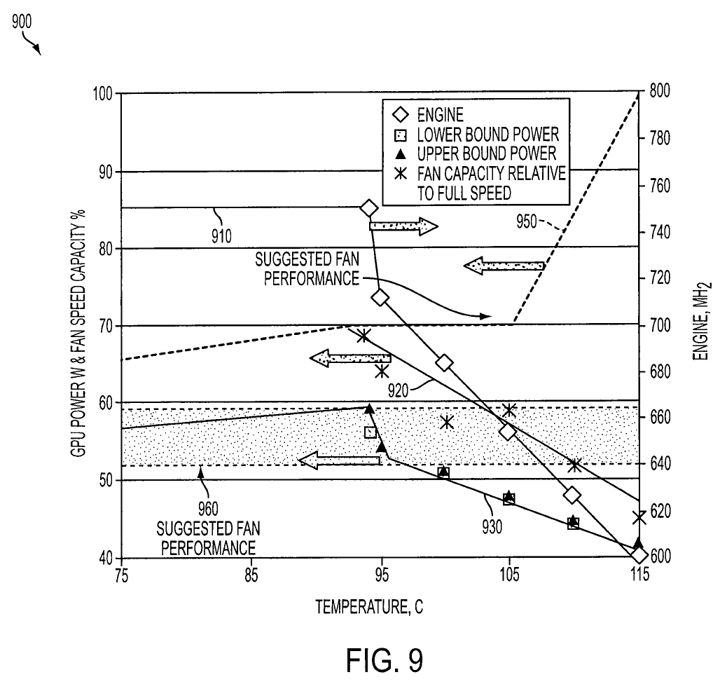

FIG. 9 depicts a graph 900 illustrating a power consumption, fan capacity, and engine speed as the power consumption, fan capacity, and engine speed vary with temperature. Graph 900 includes three curves—a first curve 910, a second curve 920, and a third curve 930. First curve 910 represents the engine speed of the GPU at different temperatures. The vertical axis scale for first curve 910 is shown on the right side of graph 900, and ranges from approximately 600 MHz to approximately 800 MHz. Second curve 920 represents the percentage of fan capacity at different temperatures. The vertical axis scale for second curve 920 is shown on the left side of graph 900, and ranges from approximately 40% of fan capacity to approximately 100% of fan capacity. Third curve 930 represents the power consumption of the GPU at different temperatures. The vertical axis scale for third curve 930 is shown on the left side of graph 900, and ranges from approximately 40 watts to approximately 100 watts.

Referring to FIG. 9, dotted line 950 illustrates a desired fan performance and shaded region 960 illustrates a desired GPU power consumption for an example GPU—namely, the RV670 offered by AMD of Sunnyvale, Calif. Graph 900 illustrates that by adjusted one or more operational parameters—which, in the example of graph 900, include the engine speed and fan speed—the power of the example GPU can be regulated within desired range 960, even as the operating conditions (e.g., temperature) of the GPU varies.

### IV. CONCLUSION

Set forth above are example systems, methods, and computer-program products for regulating power consumption in ASICs, such as GPUs. While various embodiments of the present invention have been described above, it should be understood that they have been presented by way of example only, and not limitation. It will be apparent to persons skilled in the relevant art that various changes in form and detail can be made therein without departing from the spirit and scope of the invention.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way. Thus, the breadth and scope of the present invention should not be limited by any of the above-described exemplary embodiments, but should be defined only in accordance with the following claims and their equivalents.

What is claimed is:

1. A computer-based method for regulating power consumption in an application-specific integrated circuit (ASIC), comprising:
(a) receiving a value of a leakage current of the ASIC from computer-readable information contained in the ASIC; and
(b) adjusting one or more operational parameters of the ASIC based on the value of the leakage current of the ASIC.

2. The computer-based method of claim 1, wherein the one or more operational parameters comprise at least one of (i) a supply voltage to the ASIC, (ii) an engine speed of the ASIC, and (iii) speed of a fan used to cool the ASIC.

3. The computer-based method of claim 1, wherein (b) further comprises:
adjusting the one or more operational parameters of the ASIC based on a type of application running on the ASIC.

4. The computer-based method of claim 1, further comprising:
(c) shutting off a supply voltage to the ASIC if a temperature of the ASIC exceeds a threshold.

5. The computer-based method of claim 1, wherein the ASIC comprises a graphics processing unit.

6. A computer-program product comprising a computer-readable storage medium having control logic stored therein for causing a computer to regulate power consumption in an application-specific integrated circuit (ASIC), the control logic comprising:
first computer-readable program code for causing the computer to receive a value of a leakage current of the ASIC; and
second computer-readable program code for causing the computer to adjust one or more operational parameters of the ASIC based on the value of the leakage current of the ASIC.

7. The computer-program product of claim 6, wherein the first computer-readable program code comprises:
code for causing the computer to read the value of the leakage current of the ASIC from computer-readable information contained in the ASIC.

8. The computer-program product of claim 6, wherein the one or more operational parameters comprise at least one of (i) a supply voltage to the ASIC, (ii) an engine speed of the ASIC, and (iii) speed of a fan used to cool the ASIC.

9. The computer-program product of claim 6, wherein the second computer-readable program code further comprises:
code for causing the computer to adjust the one or more operational parameters of the ASIC based on a type of application running on the ASIC.

10. The computer-program product of claim 6, further comprising:
third computer-readable program code for causing the computer to shut off a supply voltage to the ASIC if a temperature of the ASIC exceeds a threshold.

11. The computer-program product of claim 6, wherein the ASIC comprises a graphics processing unit.

12. A computing device, comprising:
an application-specific integrated circuit (ASIC); and
a machine-readable storage medium having control logic stored therein for causing the computing device to regulate power consumption in the ASIC, the control logic comprising,
first machine-readable program code for causing the computing device to receive a value of a leakage current from an ASIC, and
second machine-readable program code for causing the computing device to adjust one or more operational parameters of the ASIC based on the value of the leakage current of the ASIC.

13. The computing device of claim 12, wherein the first machine-readable program code comprises:
code for causing the computing device to read the value of the leakage current of the ASIC from machine-readable information contained in the ASIC.

14. The computing device of claim 12, wherein the one or more operational parameters comprise at least one of (i) a supply voltage to the ASIC, (ii) an engine speed of the ASIC, and (iii) speed of a fan used to cool the ASIC.

15. The computing device of claim 12, wherein the second machine-readable program code further comprises:
code for causing the computing device to adjust the one or more operational parameters of the ASIC based on a type of application running on the ASIC.

16. The computing device of claim 12, wherein the control logic further comprises:
third machine-readable program code for causing the computing device to shut off a supply voltage to the ASIC if a temperature of the ASIC exceeds a threshold.

17. The computing device of claim 12, wherein the ASIC comprises a graphics processing unit.
